(19) United States
(12) Patent Application Publication
(10) Pub. No.: US 2025/0357086 A1
(43) Pub. Date: Nov. 20, 2025

(54) PLASMA PROCESSING DEVICE

(71) Applicant: Samsung Electronics Co., Ltd., Suwon-si (KR)

(72) Inventors: Cheol Kim, Suwon-si (KR); Taewoo Kim, Suwon-si (KR); Hyungyong Kim, Suwon-si (KR); Jinho Park, Suwon-si (KR)

(21) Appl. No.: 18/986,997

(22) Filed: Dec. 19, 2024

(30) Foreign Application Priority Data
May 16, 2024 (KR) 10-2024-0064143

(51) Int. Cl. H01J 37/32

(52) U.S. Cl. CPC H01J 37/32449; H01J 37/3211; H01J 37/32715; H01J 37/32816; H01J 2237/3341

(57) ABSTRACT

Provided is a plasma processing device. The plasma processing device includes a dual chamber system including a first chamber and a second chamber fluidly connected to the first chamber through an opening, a first gas injector configured to supply a first gas to the first chamber, a grid positioned at the opening between the first chamber and the second chamber, a second chamber shutter, a second gas injector configured to inject a second gas into the second chamber, and a wafer stage positioned inside the second chamber and having a wafer support surface, wherein the second chamber shutter is configured to transition between an open state in which the grid is fluidly connected to the second chamber and a closed state in which the grid is not fluidly connected to the second chamber.

### CROSS-REFERENCE TO RELATED APPLICATION

This application is based on and claims priority under 35 U.S.C. § 119 to Korean Patent Application No. 10-2024-0064143, filed on May 16, 2024, in the Korean Intellectual Property Office, the disclosure of which is incorporated by reference herein in its entirety.

### BACKGROUND

The inventive concept relates to a plasma processing device, and more particularly, to a plasma processing device using a dual chamber system.

One example of a process that occurs during manufacturing a semiconductor device is a plasma process, such as plasma-induced deposition, plasma etching, and plasma cleaning. Recently, as semiconductor devices have become smaller and more highly integrated, the impact of a minute error in a plasma process on the quality of a semiconductor product has increased. Accordingly, various technologies for precisely performing a plasma process have been proposed.

### SUMMARY

The inventive concept provides a plasma processing device having improved reliability.

According to an aspect of the inventive concept, there is provided a plasma processing device including a dual chamber system including a first chamber and a second chamber fluidly connected to the first chamber through an opening between the first chamber and the second chamber, a first gas injector configured to supply a first gas to the first chamber, a grid positioned at the opening between the first chamber and the second chamber the grid extending along the opening and having a first side facing the first chamber and a second side facing the second chamber, a second chamber shutter positioned at the second side of the grid, a second gas injector configured to inject a second gas into the second chamber, and a wafer stage positioned inside the second chamber and having a wafer support surface, wherein the second chamber shutter is configured to transition between an open state in which the grid is fluidly connected to the second chamber and a closed state in which the grid is not fluidly connected to the second chamber.

According to another aspect of the inventive concept, there is provided a plasma processing device including a first chamber configured to form plasma, a second chamber fluidly connected to the first chamber through an opening between the first chamber and the second chamber and configured to perform reactive ion etching, a grid positioned at the opening between the first chamber and the second chamber, the grid extending along the opening and having a first side facing the first chamber and a second side facing the second chamber, a first gas injector configured to supply a first gas to the first chamber, a second gas injector configured to supply a second gas to the second chamber, a wafer stage positioned inside the second chamber and having a wafer support surface, a stage voltage supply, a first chamber shutter positioned at the first side of grid, and a second chamber shutter positioned at the second side of the grid, wherein the stage voltage supply is configured to apply a voltage to the wafer stage when the second gas is injected into the second chamber, and the first chamber shutter and the second chamber shutter are each configured to move in a direction parallel to a direction in which the grid extends between an open state in which the grid is fluidly connected to the first chamber and the second chamber and a closed state in which the grid is not fluidly connected to the first chamber and the second chamber.

According to another aspect of the inventive concept, there is provided a plasma processing device including a dual chamber system including a first chamber and a second chamber, the first chamber being configured to form plasma, and the second chamber positioned at a side of the first chamber, fluidly connected to the first chamber through an opening between the first and second chamber, and configured to perform reactive ion etching, a grid positioned at the opening between the first chamber and the second chamber the grid extending along the opening, a first gas injector configured to supply a first gas to the first chamber, a second gas injector configured to supply a second gas to the second chamber, a wafer stage positioned inside the second chamber and having a wafer support surface, a first chamber shutter positioned between the grid and the first chamber, a second chamber shutter positioned between the grid and the second chamber, a stage voltage supply, a plurality of radio frequency (RF) coils positioned at an outer wall of the first chamber, and an RF power supply unit configured to supply power to the plurality of RF coils, wherein the stage voltage supply is configured to apply a voltage to the wafer stage when the second gas is injected into the second chamber, the first chamber shutter and the second chamber shutter are each configured to slide in a direction parallel to a direction in which the grid extends between an open state in which the grid is fluidly connected to the first chamber and the second chamber and a closed state in which the grid is not fluidly connected to the first chamber and the second chamber, the second chamber shutter includes a first surface facing the second chamber and including an oxide film, and a second surface opposite to the first surface and including a metal film, the first gas injector is further configured to supply the first gas only when the first chamber shutter and the second chamber shutter are in an open state, and the second gas injector is further configured to supply the second gas only when the first chamber shutter and the second chamber shutter are in a closed state.

### BRIEF DESCRIPTION OF THE DRAWINGS

Embodiments will be more clearly understood from the following detailed description taken in conjunction with the accompanying drawings in which:

FIG. 1 is a cross-sectional view of a plasma processing device having dual chambers with a chamber shutter in an open state in a plasma processing device according to an embodiment;

FIG. 2 is a cross-sectional view of a plasma processing device having dual chambers with a chamber shutter in a closed state in a plasma processing device according to an embodiment;

FIG. 3 is an enlarged cross-sectional view of region A of FIG. 2 according to an embodiment;

FIG. 4 is an enlarged cross-sectional view of region A of FIG. 2 according to another embodiment;

FIG. 5 is an enlarged cross-sectional view of region A of FIG. 2 according to another embodiment;

FIG. 6 is an enlarged view conceptually showing removal of a redeposited material in region B of FIG. 2;

FIG. 7 is a flowchart of a method of manufacturing a semiconductor device, the method including a plasma process, according to an embodiment;

FIG. 8 is a flowchart of detailed operations included in operation S30 of FIG. 7;

FIG. 9 is a configuration diagram showing each memory cell included in a memory cell array produced at least partially by a plasma processing device, according to an embodiment;

FIGS. 10 and 11 are conceptual diagrams showing data stored according to a magnetization direction in a magnetic tunnel junction (MTJ) structure of a memory cell produced at least partially by a plasma processing device, according to an embodiment; and

FIG. 12 is a conceptual diagram showing a magnetization direction according to a write operation in an MTJ structure of a memory cell produced by a plasma processing device, according to an embodiment.

### DETAILED DESCRIPTION OF THE EMBODIMENTS

Embodiments set forth herein may have various modifications and various forms, and thus, some embodiments will be illustrated in the drawings and described in detail. However, this is not intended to limit the inventive concept to specific disclosed forms. Also, the embodiments described below are merely illustrative, and various modifications may be made to these embodiments.

The use of all examples or illustrative terms is merely for describing the inventive concept in detail, and thus, the scope of the inventive concept is not limited by these examples or illustrative terms. The language of the claims should be referenced in determining the requirements of the inventive concept.

Hereinafter, unless otherwise specified, in the present specification, a vertical direction may be defined as a Z direction, and a first horizontal direction and a second horizontal direction may each be defined as a horizontal direction that is perpendicular to the Z direction. The first horizontal direction may be referred to as X, and the second horizontal direction may be referred to as Y. A vertical level may refer to a height level in the vertical direction (Z). A horizontal width may refer to a length in the horizontal direction (X and/or Y), and a vertical length may refer to a length in the vertical direction (Z).

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, items described as being “fluidly connected” are configured such that a liquid or gas can flow, or be passed, from one item to the other.

Terms such as “same,” “equal,” etc. as used herein when referring to features such as orientation, layout, location, shapes, sizes, compositions, amounts, or other measures do not necessarily mean an identical feature but is intended to encompass nearly identical features including typical variations that may occur resulting from conventional manufacturing processes. The term “substantially” may be used herein to emphasize this meaning.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

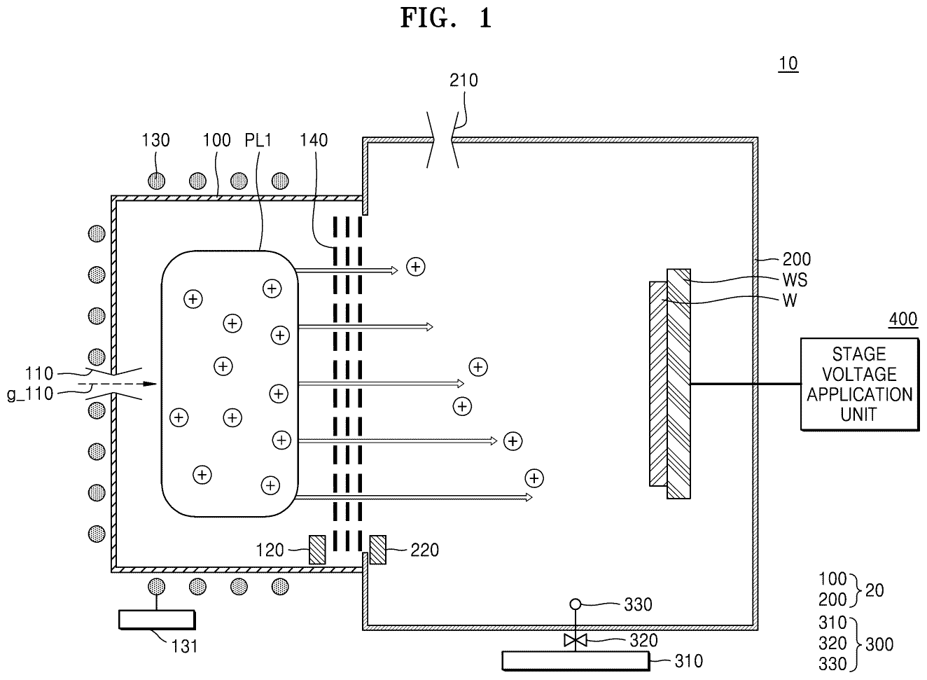

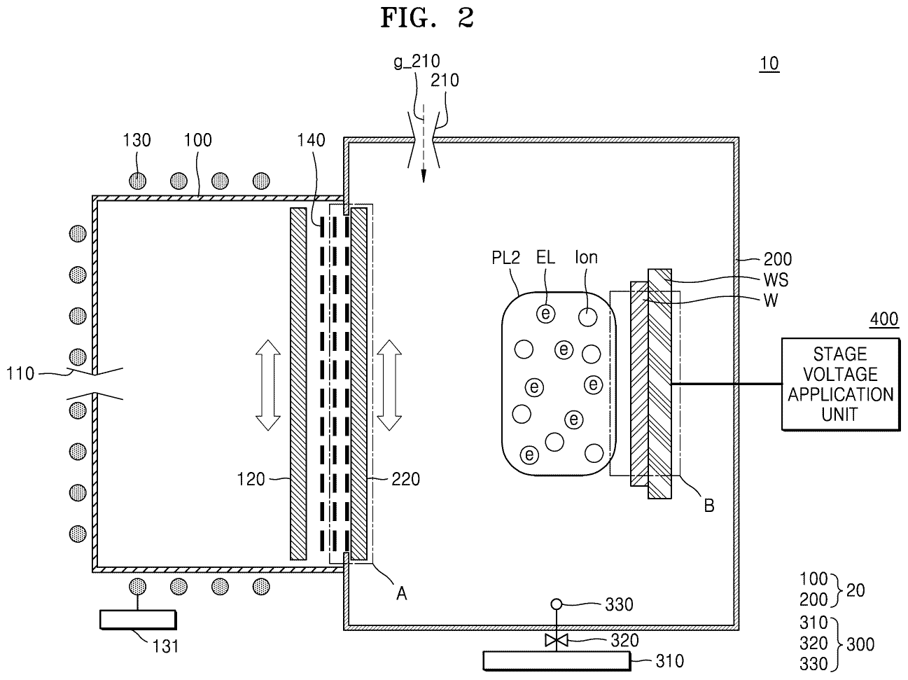

FIG. 1 is a cross-sectional view of dual chambers having a chamber shutter in an open state in a plasma processing device according to an embodiment. FIG. 2 is a cross-sectional view of the dual chambers having a chamber shutter in a closed state in the plasma processing device according to an embodiment.

FIGS. 1 and 2 will be referred to together. A plasma processing device 10 may include a dual chamber system 20. The dual chamber system 20 may include a first chamber 100 and a second chamber 200 arranged (e.g., positioned) on one side of the first chamber 100. The first chamber 100 and the second chamber 200 may perform different roles. In an embodiment, the first chamber 100 may be a plasma chamber that forms plasma. In an embodiment, the second chamber 200 may be a process chamber. The process in the process chamber may be a process of generating plasma that is different from the plasma generated in the first chamber 100, a process of generating reactive ions, and/or a process of performing reactive ion beam etching through the reactive ions. Plasma generated in the first chamber 100 may be inductively coupled plasma (ICP), and plasma generated in the second chamber 200 may be capacitively coupled plasma (CCP). That is, the plasma generated in the first chamber 100 may be different from the plasma generated in the second chamber 200. The first chamber 100 and the second chamber 200 may be operated independently. That is, the dual chamber system 20 may independently control the plasma for each of the two chambers, the first chamber 100 and the second chamber 200. The first chamber 100 and the second chamber 200 may have different sizes. The first chamber 100 and the second chamber 200 may include different materials. The first chamber 100 and the second chamber 200 may have a common opening such that the first chamber 100 is fluidly connected to the second chamber 200 through the opening.

The plasma processing device 10 may include a first gas injection unit 110 (e.g., a gas injector). The first gas injection unit 110 may supply a first gas g_110 to the first chamber 100. The first gas g_110 may include at least one process gas, such as CF₄, CH₂F₂, CH₃F, CHF₃, Cl₂, Ar, or O₂, other types of process gases, or a combination thereof. The first gas injection unit 110 may include a nozzle in fluid communication with a first gas source. A valve or other controller may regulate the flow of the first gas supplied by the first gas injection unit 110.

The plasma processing device 10 may generate first plasma PL1 from the first gas g_110 and may further include a plurality of radio frequency (RF) coils 130 arranged on or at an outer wall of the first chamber 100. That is, the RF coils 130 may be arranged to surround an outer peripheral surface of the first chamber 100. The plasma processing device 10 may include an RF power supply unit 131 (e.g., an RF power supply) that supplies power to the RF coils 130. Although the RF power supply unit 131 is shown as being connected to one RF coil 130 in the drawings, the RF power supply unit 131 may be connected to each of the plurality of RF coils 130. After the RF power supply unit 131 applies power to the RF coils 130, the RF coils 130 may apply RF power to the first chamber 100 to generate first plasma PL1 from the first gas g_110. The RF coils 130 may form a high-frequency electric field that generates plasma inside the first chamber 100 from the first gas g_110. The RF power supply unit 131 may include a magnetic material. The magnetic material may uniformly control the distribution of plasma generated by the RF coils 130. By adjusting the amount of current provided to the magnetic material, the distribution of plasma may be controlled.

The plasma processing device 10 may further include a first chamber shutter 120 arranged inside the first chamber 100. The first chamber shutter 120 will be described in detail together with a second chamber shutter 220, which will be described below.

The plasma processing device 10 may further include a grid 140 arranged or positioned between the first chamber 100 and the second chamber 200. The grid 140 may be a plasma grid. The grid 140 may be positioned to cover or fill the opening between the first chamber 100 and the second chamber 200. The grid 140 may have a first side that faces the first chamber 100 and a second side that faces the second chamber 200. The grid 140 may include a plurality of columns. Although FIGS. 1 and 2 show a grid 140 including three columns for convenience, the number of columns of the grid 140 is not limited to the number shown in the drawings. A plurality of grids 140 may be provided, wherein a first set of the plurality of grids 140 may be arranged adjacent to the first chamber 100, and a second set of the plurality of grids 140 may be arranged adjacent to the second chamber 200. Also, a third set of grids 140 may be arranged between the first set of grids 140 and the second set of grids 140. In an embodiment, the grids 140 may have substantially the same size as one another. Also, intervals or spacing between adjacent grids may be substantially the same for the plurality of grids 140. At least some of the grids 140 may be connected to different electrodes, respectively. In an embodiment, a grid 140 that is closest to the first chamber 100 may be connected to an anode. A grid arranged in the center (e.g., between a grid 140 closest to the first chamber 100 and a grid 140 closest to the second chamber 200) may be connected to a cathode. A grid 140 closest to the second chamber 200 may be grounded. The grid 140 may have a plurality of openings or cavities through which ion beams, which will be described below, pass. The openings or cavities may have substantially the same size as one another. The cavities or openings may be arranged along substantially the same axis.

The plasma processing device 10 may include a first chamber shutter 120 arranged between the grid 140 and the first chamber 100 (e.g., at the first side of the grid 140) and a second chamber shutter 220 arranged between the grid 140 and the second chamber 200 (e.g., at the second side of the grid 140). The first chamber shutter 120 and the second chamber shutter 220 may be formed to have substantially the same physical properties. The second chamber shutter 220 may include two dualized surfaces. In an embodiment, the second chamber shutter 220 may include a first surface facing the second chamber 200 and the first surface may include an oxide film. Also, the second chamber shutter 220 may include a second surface opposite to the first surface and the second surface may include a metal film. The two dualized surfaces of the second chamber shutter 220 may be applied to the first chamber shutter 120 in a like manner. Accordingly, by the inclusion of the metal film, scattering of reactive ion beams, which will be described below, may be prevented. That is, the chamber shutters may prevent reactive ion beams from penetrating the grid 140 and entering the first chamber 100.

The first chamber shutter 120 and the second chamber shutter 220 may each transition between an open state and a closed state. For example, a shutter may move or slide in a door-like manner in a direction parallel to a direction in which the grid 140 extends. The first chamber shutter 120 and the second chamber shutter 220 may each move or slide or slide between two different positions in which a first position corresponds to an open state and a second position corresponds to a closed state. The first chamber 100 and the second chamber 200 may each be in an open state or a closed state depending on their position. In an embodiment, the first chamber shutter 120 and the second chamber shutter 220 as shown in FIG. 1 may be in the open state. Here, the open state means that two sides of the grid 140 are open, and the first chamber 100 and the second chamber 200 spatially correspond to one open system (e.g., the first chamber 100 and the second chamber 200 are fluidly connected). That is, in the open state, the first plasma PL1 formed in the first chamber 100 may penetrate through or pass through the grid 140 to reach the second chamber 200. In an embodiment, the first chamber shutter 120 and the second chamber shutter 220 as shown in FIG. 2 may be in the closed state. Here, the closed state means that two sides of the grid 140 are blocked, and the first chamber 100 and the second chamber 200 spatially correspond to closed systems (e.g., the first chamber 100 and the second chamber 200 are not fluidly connected), respectively. That is, in the closed state, the first plasma PL1 formed in the first chamber 100 may not penetrate through or pass through the grid 140 to reach the second chamber 200, and second plasma PL2, including ions, etc., formed in the second chamber 200 also may not reach the first chamber 100 through the grid 140. When the first chamber shutter 120 and the second chamber shutter 220 are closed, plasma control may be independently performed for each of the first chamber 100 and the second chamber 200.

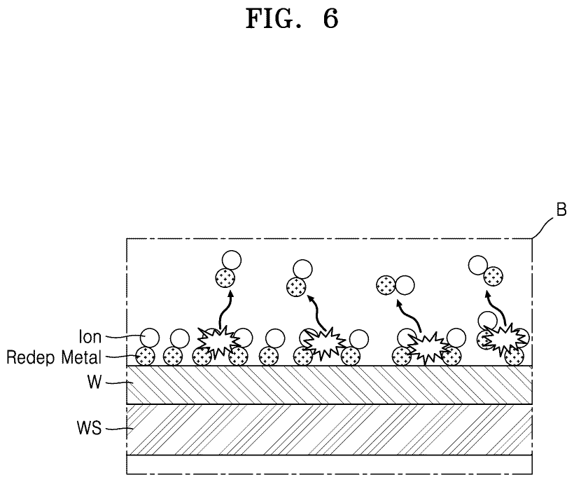

The plasma processing device 10 may include a second gas injection unit 210 that injects a second gas g_210 into the second chamber 200. The second gas g_210 may be separated as ions and electrons EL in the second chamber 200. The ions may be configured (e.g., suitable) to remove a redeposited metal that is separated from a wafer W on which ion beam etching has been performed by the first plasma PL1 that was generated in the first chamber 100. The second gas g_210 may include one of chlorine (Cl₂), carbon fluoride (CF), hydrogen bromide (HBr), methanol, or a combination thereof. In an embodiment, the second gas g_210 may include at least one halogen element of Group 17. Details on the removal of the redeposited metal by the ions will be described with reference to FIG. 6.

The plasma processing device 10 may include a wafer stage WS that is arranged inside the second chamber 200 and supports the wafer W. The wafer stage WS may have a support surface that supports a wafer that is disposed thereon. Also, the plasma processing device 10 may include a stage voltage application unit 400. The stage voltage application unit 400 may apply a voltage to the wafer stage WS when the second gas g_210 is injected into the second chamber 200. The stage voltage application unit 400 may be electrically connected to the wafer stage WS. The wafer stage WS may include an electrostatic chuck (ESC) or may itself be an electrostatic chuck (ESC). An alternating current power supply and a plurality of capacitors, which are controlled through the stage voltage application unit 400, may be electrically connected to the wafer stage WS. The voltage applied to the wafer stage WS may supply energy to convert the second gas g_210, which will be described below, into a second plasma PL2, which is CCP.

The first gas g_110 supplied to the first chamber 100 may be converted into first plasma PL1 by the RF coils 130, and the first plasma PL1 may be supplied to the second chamber 200 to be used to perform ion beam etching on the wafer W. Ion beam-based sputtering etching is a method of etching which removes the physical bonding force of the wafer W, and an etched material may have a strong tendency to be redeposited on the wafer W. Accordingly, the etched material may be redeposited on a sidewall of a magnetic tunnel junction (MTJ) film. When the etched material is redeposited on the MTJ film, an electrical short circuit defect, which electrically connects an upper layer to a lower layer, may occur.

The second gas g_210 supplied to the second chamber 200 may be converted into second plasma PL2. The second plasma PL2 may include ions and electrons EL, and the ions may be used to remove a redeposited metal that is separated from the wafer W on which the ion beam etching has been performed. For example, the second plasma PL2 may be used to perform a reactive ion etch process. The second gas g_210 may be separated into ions and electrons EL by a voltage having passed through a capacitor, which is supplied to the wafer stage WS. A voltage may be applied to the wafer stage WS by the stage voltage application unit 400. When the second gas g_210 is supplied to the second chamber 200, the first chamber shutter 120 and the second chamber shutter 220 may slide to be in the closed position corresponding to a closed state. The second gas injection unit 210 may supply the second gas g_210 to the second chamber 200 only when the second chamber shutter 220 is in the closed state. Also, the second gas injection unit 210 may supply the second gas g_210 to the second chamber 200 only when the second chamber shutter 220 and the first chamber shutter 120 are in the closed state at the same time. Accordingly, the operation of the second chamber 200 using the second gas g_210 may not affect the first chamber 100. The first chamber 100 and the second chamber 200 may independently generate plasma to perform plasma processing. While the second gas injection unit 210 supplies the second gas g_210 to the second chamber 200, the first gas injection unit 110 may not supply the first gas g_110 to the first chamber 100.

Referring to FIG. 1, when the first gas g_110 is supplied to the first chamber 100 from the first gas injection unit 110, the first chamber shutter 120 and the second chamber shutter 220 may be in the open state. When the first gas g_110 is supplied to the first chamber 100, the second gas injection unit 210 may not supply the second gas g_210 to the second chamber 200. Thus, while the first chamber 100 is operating to produce the first plasma PL1, the second chamber 200 may not affect the operation of the first chamber 100. Accordingly, the first chamber 100 and the second chamber 200 may independently generate plasma to perform plasma processing, as described above.

Referring to FIG. 2, when the second gas g_210 is supplied to the second chamber 200 from the second gas injection unit 210, the first chamber shutter 120 and the second chamber shutter 220 may be in the closed state. When the second gas g_210 is supplied to the second chamber 200, the first gas injection unit 110 may not supply the first gas g_110 to the first chamber 100. Thus, while the second chamber 200 is operating, the first chamber 100 may not affect the operation of the second chamber 200. Also, while the second chamber 200 is operating, the operation of the second chamber 200 may not affect the first chamber 100.

The plasma processing device 10 may include a vacuum unit 300 that supplies a vacuum to the second chamber 200. The vacuum unit 300 may include a vacuum pump 310 that generates vacuum pressure, a suction port 330 that sucks in a gas by applying vacuum to the second chamber 200, and a vacuum valve 320 that is arranged between the vacuum pump 310 and the suction port 330 and adjusts or controls the vacuum pressure. The suction port may be an opening in the second chamber 200 that is fluidly connected to the vacuum pump 310. The vacuum valve 320 may change the fluid connection between the vacuum pump 310 and the suction port 330 by partially or completely blocking the fluid connection. Byproducts of an etching reaction resulting from ion beam etching and reactive ion beam etching may be discharged to the outside of the second chamber 200 through the vacuum unit 300.

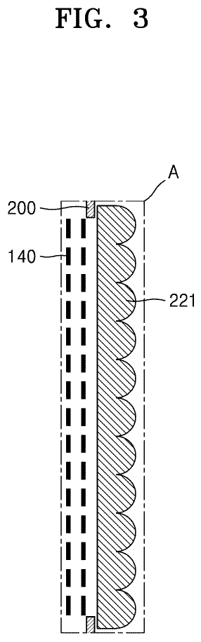

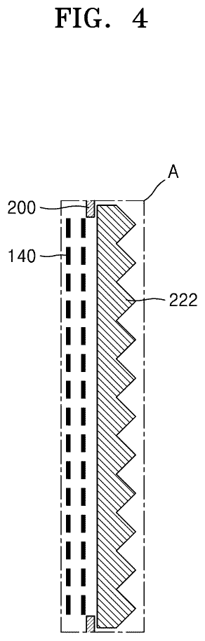

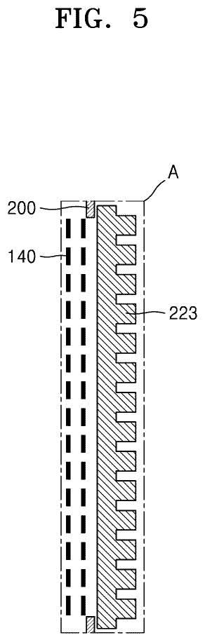

FIG. 3 is an enlarged cross-sectional view of region A of FIG. 2 according to an embodiment. FIG. 4 is an enlarged cross-sectional view of region A of FIG. 2 according to another embodiment. FIG. 5 is an enlarged cross-sectional view of region A of FIG. 2 according to another embodiment.

FIGS. 3 to 5 will be described with reference to FIGS. 1 and 2. Details of a second chamber shutter described with reference to FIGS. 3 to 5 may be applied to a first chamber shutter in a similar manner. Since the description of the details of the first chamber shutter may be redundant with the descriptions of the details of the second chamber shutter, they may be omitted hereafter.

The second chamber shutter 220 may have, in a portion thereof facing the second chamber 200, a shape in which a side surface facing the second chamber 200 has a constant level, as shown in FIGS. 1 and 2 (e.g., the surface may be planar). In some embodiments, a second chamber shutter 221 may have, in a portion thereof facing the second chamber 200, a side surface with a series of round semicircular shapes, as shown in FIG. 3. The round semicircular shapes may be semi hemispherical as well. The round semicircular shapes increase the surface area of the second chamber shutter 221 facing the second chamber 200, and the lifespan of the second chamber shutter 221 consumed in processing a redeposited material may be extended thereby. The curvature and the number of round semicircular shapes are not limited to those shown in the drawing. In some embodiments, a second chamber shutter 222 may have a side surface with a series of triangular shapes in which a series of peak points are formed, as shown in FIG. 4. The triangular shapes may be pyramid shapes. The triangular shapes in which peak points are formed, as in the case of the round semicircular shapes, increase the surface area of the second chamber shutter 222 facing the second chamber 200, and the lifespan of the second chamber shutter 222 consumed in processing a redeposited material may be extended thereby. The slope and the number of triangular shapes are not limited to those shown in the drawing. In some embodiments, a second chamber shutter 223 may have, in a portion thereof facing the second chamber 200, a side surface with an uneven shape, as shown in FIG. 5. The uneven shape increases the surface area of the second chamber shutter 223 facing the second chamber 200, and the lifespan of the second chamber shutter 223 consumed in processing a redeposited material may be extended thereby. The depth and number of uneven shapes are not limited to those shown in the drawing.

FIG. 6 is an enlarged view conceptually showing the removal of a redeposited material in region B of FIG. 2.

Referring to FIG. 6, a redeposited metal may be formed on an upper surface of the wafer W after ion beam etching has been performed on the wafer W (e.g., after using the first plasma PL1 to perform ion beam etching). Ions separated from the second gas bind to the redeposited metal. In an embodiment, the ions may be halogen ions, such as chlorine ions (Cl—) or fluorine ions (F—), but are not limited thereto and may correspond to methanol molecules. The ions bound to the redeposited metal may then be separated from the wafer W thereby removing the redeposited metal bound to the ion. For example, a reactive ion etch using the second plasma PL2 may remove the redeposited metal bound to the ion. Ion molecules bound to the redeposited metal, which has been separated from the wafer W, may be absorbed and removed by the vacuum unit described above. Through the above process, the redeposited metal present on the upper surface of the wafer W may be removed, and a short circuit of an MTJ may be prevented.

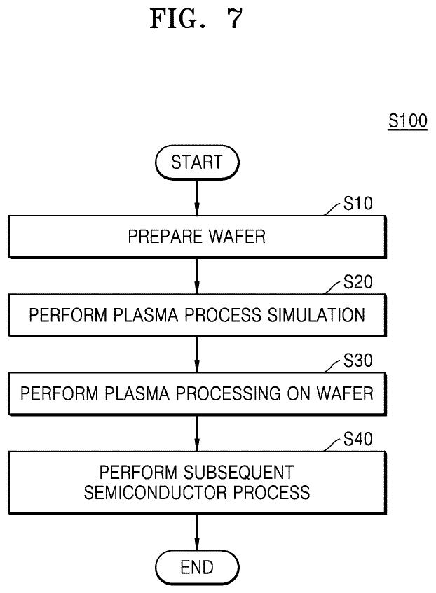

FIG. 7 is a flowchart of a method of manufacturing a semiconductor device, the method including a plasma process, according to an embodiment.

Referring to FIG. 7, in operation S10, the wafer W may be prepared inside the second chamber 200. For example, the wafer W may be arranged (e.g., placed) on the wafer stage WS of the second chamber 200. For example, the wafer stage WS may be an ESC and may apply a voltage to the wafer W. The voltage applied to the wafer W may be controlled by the stage voltage application unit 400.

In operation S20, a plasma process simulation may be performed on the wafer W. For example, a plasma process may include any plasma processes, such as a plasma etching process, a plasma annealing process, and/or a plasma cleaning process and the plasma process simulation may simulate the plasma process.

The plasma process of operation S20 may include defining a plasma reaction, calculating a reaction parameter, generating a plasma process simulation profile, and generating a final simulation profile.

After the wafer W is prepared inside the second chamber 200, in operation S30, plasma processing may be performed on the wafer W. In some embodiments, the plasma processing may be based on a plasma process simulation, such as in operation S20. Operation S30, that is, the plasma processing, may include a plasma process such as an etching process, a deposition process, a cleaning process, etc. on the wafer W using plasma.

After the plasma processing on the wafer W, in operation S40, a subsequent semiconductor process may be performed on the wafer W. The subsequent semiconductor process on the wafer W may include various processes. For example, the subsequent semiconductor process may include a deposition process, an etching process, an ion process, a cleaning process, etc. Plasma may or may not be used in the subsequent semiconductor process. Also, the subsequent semiconductor process may include a singulation process of separating the wafer W into individual semiconductor chips, a test process of testing the semiconductor chips, and a packaging process of packaging the semiconductor chips. Through the subsequent semiconductor process on the wafer W, a semiconductor device may be completed.

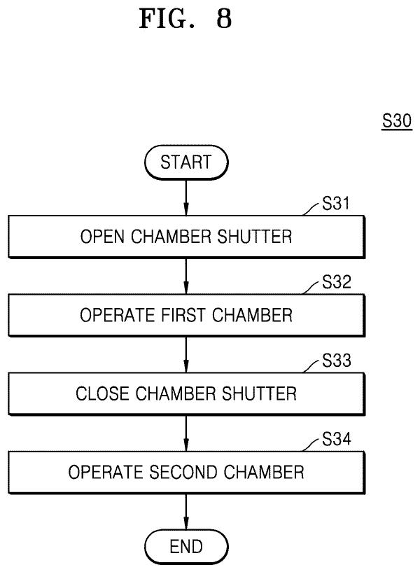

FIG. 8 is a flowchart of detailed operations included in operation S30 of FIG. 7.

Referring to FIG. 8 together with FIGS. 1 and 2, operation S30, which is a plasma processing operation, may include operation S31 of opening a chamber shutter so that the chamber shutter is in an open state. The chamber shutter may include the first chamber shutter 120 as well as the second chamber shutter 220. The chamber shutters being in an open state means that the chamber shutters are in a position such that two sides of the grid 140 are open (e.g., a first side may be open to the first chamber 100 and a second side may be open to the second chamber), as shown in FIG. 1. The chamber shutters may slide or move to enter the open state. After operation S31 is performed, operation S30 may include operation S32 of operating the first chamber 100. The operation of the first chamber 100 may include supplying the first gas g_110 to the first chamber 100 through the first gas injection unit 110, and generating first plasma PL1 from the first gas g_110 as described previously. The first plasma PL1 may be ICP. The first plasma PL1 thus generated may be used to perform ion beam etching on the wafer W. After operation S32 is performed, operation S33 of closing a chamber shutter may be performed. The chamber shutter may include the first chamber shutter 120 as well as the second chamber shutter 220. However, in some embodiments, in operation S33 only the second chamber shutter 220 is closed. The chamber shutters being in a closed state means that the chamber shutters are in a position such that two sides of the grid 140 are blocked, as shown in FIG. 2. The chamber shutters may move or slide to enter the closed state. After operation S33 is performed, operation S30 may include operation S34 of operating the second chamber 200. The operation of the second chamber 200 includes supplying the second gas g_210 to the second chamber 200 through the second gas injection unit 210, and generating the second plasma PL2 including ions and electrons EL from the second gas g_210 as described previously. The second plasma PL2 may be CCP. The second plasma PL2 thus generated may be used to perform reactive ion etching on the wafer W on which the ion beam etching has been performed. Also, because the chamber shutter is closed while the reactive ion etching is performed, damage to the grid 140 may be reduced, and the lifespan of the grid 140 may be extended.

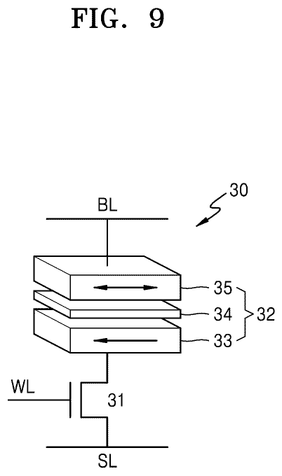

FIG. 9 is a configuration diagram showing each memory cell included in a memory cell array produced by a plasma processing device, according to an embodiment.

FIG. 9 shows a normal memory cell 30 among memory cells included in a memory cell array produced by the plasma processing device 10 (see FIG. 1) according to an embodiment.

The normal memory cell 30 may include a selection transistor 31 and an MTJ structure 32. A gate of the selection transistor 31 may be connected to a word line WL, and one electrode, for example, a drain electrode, of the selection transistor 31 may be connected to a bit line BL through the MTJ structure 32. Also, the other electrode, for example, a source electrode, of the selection transistor 31 may be connected to a source line SL.

The MTJ structure 32 may include a pinned layer 33, a free layer 35, and a tunnel barrier layer 34 therebetween. A magnetization direction of the pinned layer 33 may be fixed, and a magnetization direction of the free layer 35 may be parallel (P) or anti-parallel (AP) to the magnetization direction of the pinned layer 33, according to data stored through a write operation. To fix a magnetization direction of the pinned layer 33, an anti-ferromagnetic layer may be further provided.

The pinned layer 33 may include a ferromagnetic material. For example, the pinned layer 33 may include at least one of CoFeB, Fe, Co, Ni, Gd, Dy, CoFe, NiFe, MnAs, MnBi, MnSb, CrO, MnOFeO, FeOFeO, NiOFeO, CuOFeO, MgOFeO, EuO, or YFeO.

The tunnel barrier layer 34 may include a non-magnetic material. For example, the tunnel barrier layer 34 may include at least one of magnesium (Mg), titanium (Ti), aluminum (Al), magnesium zinc oxide (MgZnO), titanium nitride (TiN), or vanadium nitride (VN).

The free layer 35 may include a ferromagnetic material including cobalt (Co), iron (Fe), or nickel (Ni). For example, the free layer 35 may include at least one of FeB, Fe, Co, Ni, Gd, Dy, CoFe, NiFe, MnAs, MnBi, MnSb, CrO, MnOFeO, FeOFeO, NiOFeO, CuOFeO, MgOFeO, EuO, or YFeO.

In some embodiments, when the free layer 35 and the pinned layer 33 of the MTJ structure 32 are in a parallel (P) state, that is, when the MTJ structure 32 exhibits low resistance, the normal memory cell 30 is defined as being in a data zero (0) logic state. In contrast, when the free layer 35 and the pinned layer 33 of the MTJ structure 32 are in an anti-parallel (AP) state, that is, when the MTJ structure 32 exhibits high resistance, the normal memory cell 30 is defined as being in a data one (1) logic state. In other embodiments, the normal memory cell 30 may be defined as being in the data 0 logic state when the MTJ structure 32 is in the AP state and may be defined as being in the data 1 logic state when the MTJ structure 32 is in the P state.

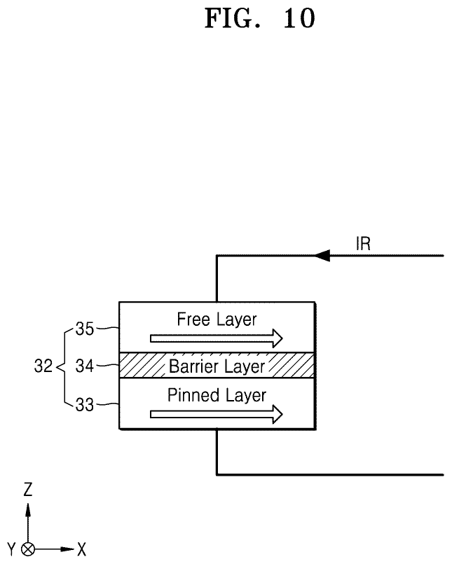

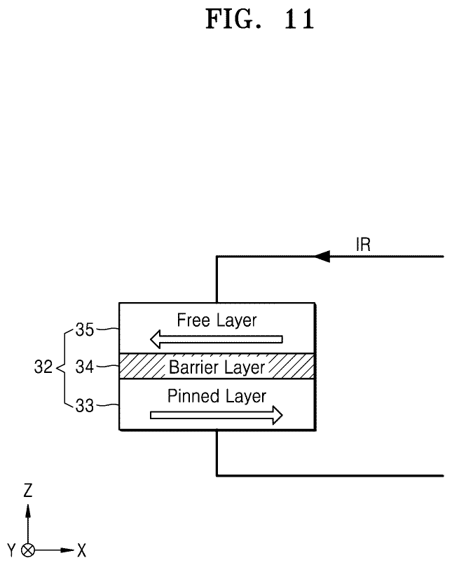

FIGS. 10 and 11 are conceptual diagrams showing data stored according to a magnetization direction in a MTJ structure of a memory cell produced by a plasma processing device, according to an embodiment.

Referring to FIGS. 10 and 11, a resistance value of the MTJ structure 32 may vary according to a magnetization direction of the free layer 35.

When a read current IR flows in the MTJ structure 32, a data voltage according to a resistance value of the MTJ structure 32 may be output. Because the intensity of the read current IR is much smaller than that of a write current, a magnetization direction of the free layer 35 is not changed due to the read current IR.

As shown in FIG. 10, a magnetization direction of the free layer 35 and a magnetization direction of the pinned layer 33 may be parallel to each other in the MTJ structure 32. The MTJ structure 32 in this state may have a low resistance value, and data 0 may be output through a read operation.

As shown in FIG. 11, a magnetization direction of the free layer 35 and a magnetization direction of the pinned layer 33 may be anti-parallel to each other in the MTJ structure 32. The MTJ structure 32 in this state may have a high resistance value, and data 1 may be output through a read operation.

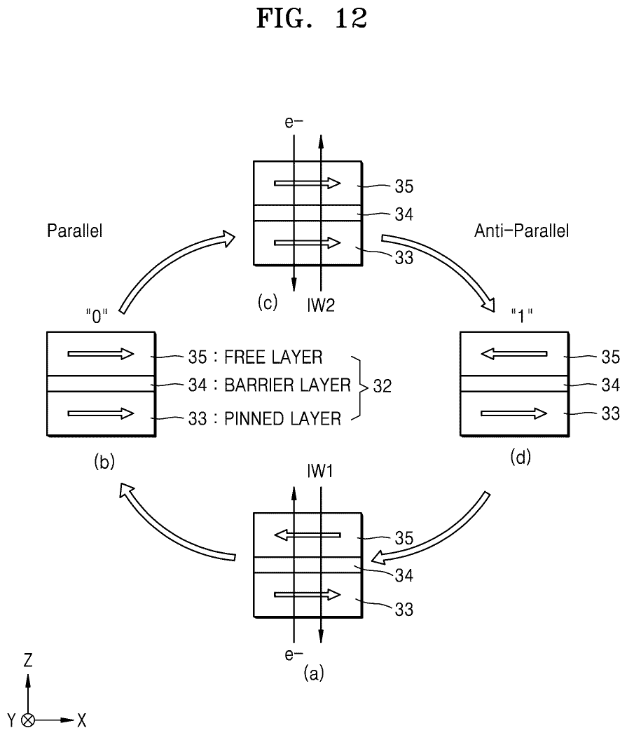

FIG. 12 is a conceptual diagram showing a magnetization direction according to a write operation in an MTJ structure of a memory cell produced by a plasma processing device, according to an embodiment.

Referring to FIG. 12, a magnetization direction of the free layer 35 may be determined according to a direction of a write current, for example, first and second write currents IW1 and IW2, that flows in the MTJ structure 32.

When the first write current IW1 is applied from the free layer 35 to the pinned layer 33 as shown in (a), free electrons having a spin direction that is the same as that of the pinned layer 33 apply a torque to the free layer 35. As a result, the free layer 35 may be magnetized parallel to the pinned layer 33. Accordingly, data O having a low resistance value may be stored in the MTJ structure 32, as shown in (b).

In the MTJ structure 32 that is in a data 0 logic state, when the second write current IW2 is applied from the pinned layer 33 to the free layer 35 as shown in (c), free electrons having a spin direction that is opposite to that of the pinned layer 33 return to the free layer 35 to apply a torque to the free layer 35. As a result, the free layer 35 may be magnetized anti-parallel to the pinned layer 33. Accordingly, data 1 having a high resistance value may be stored in the MTJ structure 32, as shown in (d).

That is, in the MTJ structure 32, a magnetization direction of the free layer 35 may be changed to be parallel or anti-parallel to the pinned layer 33 due to a spin transfer torque (STT), and thus, data 0 or 1 may be stored.

While the inventive concept has been particularly shown and described with reference to embodiments thereof, it will be understood that various changes in form and details may be made therein without departing from the spirit and scope of the following claims.

What is claimed is:

1. A plasma processing device comprising:
a dual chamber system including a first chamber and a second chamber fluidly connected to the first chamber through an opening between the first chamber and second chamber;
a first gas injector configured to supply a first gas to the first chamber;
a grid positioned at the opening between the first chamber and the second chamber, the grid extending along the opening and having a first side facing the first chamber and a second side facing the second chamber;
a second chamber shutter positioned at the second side of the grid;
a second gas injector configured to inject a second gas into the second chamber; and
a wafer stage positioned inside the second chamber and having a wafer support surface,
wherein the second chamber shutter is configured to transition between an open state in which the grid is fluidly connected to the second chamber and a closed state in which the grid is not fluidly connected to the second chamber.

2. The plasma processing device of claim 1, further comprising a first chamber shutter positioned at the first side of the grid,
wherein the first chamber shutter is configured to transition between an open state in which the grid is fluidly connected to the first chamber and a closed state in which the grid is not fluidly connected to the first chamber.

3. The plasma processing device of claim 1, further comprising a stage voltage supply,
wherein the stage voltage supply is configured to apply a voltage to the wafer stage when the second gas is injected into the second chamber.

4. The plasma processing device of claim 2, wherein the first gas injector is further configured to supply the first gas when the first chamber shutter and the second chamber shutter are in an open state, and to not supply the first gas when the first chamber shutter and the second chamber shutter are not in the open state.

5. The plasma processing device of claim 1, wherein the second gas injector is further configured to supply the second gas when the second chamber shutter is in a closed state, and to not supply the second gas when the second chamber shutter is not in the closed state.

6. The plasma processing device of claim 1, further comprising a plurality of radio frequency (RF) coils positioned at an outer wall of the first chamber,
wherein the plurality of RF coils are configured to apply RF power to the first chamber to generate first plasma from the first gas.

7. The plasma processing device of claim 6, wherein the first plasma is configured to perform ion beam etching on a wafer,
the second chamber is configured to separate the second gas into ions and electrons, and
the ions are configured to remove a redeposited metal that is separated from the wafer on which the ion beam etching has been performed.

8. The plasma processing device of claim 1, wherein the second gas includes one of chlorine (Cl₂), carbon fluoride (CF), hydrogen bromide (HBr), methanol, or a combination thereof.

9. The plasma processing device of claim 1, wherein a side surface of the second chamber shutter facing away from the grid has one of a constant level or a series of round semicircular shapes.

10. The plasma processing device of claim 1, wherein a side surface of the second chamber shutter facing the second chamber has one of a series of triangular shapes in which a series of peak points are formed, or an uneven shape.

11. A plasma processing device comprising:
a first chamber configured to form plasma;
a second chamber positioned on the first chamber and fluidly connected to the first chamber through an opening between the first chamber and second chamber;
a grid positioned at the opening between the first chamber and the second chamber, the grid extending along the opening and having a first side facing the first chamber and a second side facing the second chamber;
a first gas injector configured to supply a first gas to the first chamber;
a second gas injector configured to supply a second gas to the second chamber;
a wafer stage positioned inside the second chamber and having a wafer support surface;
a stage voltage supply;
a first chamber shutter positioned at the first side of the grid; and
a second chamber shutter positioned at the second side of the grid,
wherein the stage voltage supply is configured to apply a voltage to the wafer stage when the second gas is injected into the second chamber, and
the first chamber shutter and the second chamber shutter are each configured to move in a direction parallel to a direction in which the grid extends between an open state in which the grid is fluidly connected to the first chamber and the second chamber and a closed state in which the grid is not fluidly connected to the first chamber and the second chamber.

12. The plasma processing device of claim 11, further comprising:
a plurality of radio frequency (RF) coils positioned at an outer wall of the first chamber; and
an RF power supply configured to supply power to the plurality of RF coils,
wherein the plurality of RF coils are configured to apply RF power to the first chamber to generate first plasma from the first gas, and
the first plasma passes through the grid to perform ion beam etching on a wafer.

13. The plasma processing device of claim 12, wherein the second chamber is configured to separate the second gas into ions and electrons, and
the ions are configured to remove a redeposited metal that is separated from the wafer on which the ion beam etching has been performed.

14. The plasma processing device of claim 11, wherein the second chamber shutter includes:
a first surface facing the second chamber and including an oxide film; and
a second surface opposite to the first surface and including a metal film.

15. The plasma processing device of claim 11, wherein the first gas injector is further configured to supply the first gas only when the first chamber shutter and the second chamber shutter are positioned in an open state, and
the second gas injector is further configured to supply the second gas only when the first chamber shutter and the second chamber shutter are in a closed state.

16. The plasma processing device of claim 11, wherein the second gas includes one of chlorine (Cl₂), carbon fluoride (CF), hydrogen bromide (HBr), methanol, or a combination thereof.

17. The plasma processing device of claim 11, wherein a side surface of the second chamber shutter facing away from the grid has a constant level, a series of round semicircular shapes, a series of triangular shapes in which a series of peak points are formed, or an uneven shape.

18. The plasma processing device of claim 11, further comprising a vacuum source configured to supply vacuum to the second chamber,
wherein the vacuum source includes:
a vacuum pump configured to generate vacuum pressure;
a suction port fluidly connected to the second chamber to vacuum in a gas through the application of the vacuum pressure; and
a vacuum valve fluidly connected to the vacuum pump and the suction port and positioned between the vacuum pump and the suction port, the vacuum valve configured to adjust the vacuum pressure.

19. A plasma processing device comprising:
a dual chamber system including a first chamber and a second chamber, the first chamber being configured to form plasma, and the second chamber being positioned at a side of the first chamber, fluidly connected to the first chamber through an opening between the first chamber and second chamber, and configured to perform reactive ion etching;
a grid positioned at the opening between the first chamber and the second chamber, the grid extending along the opening;
a first gas injector configured to supply a first gas to the first chamber;
a second gas injector configured to supply a second gas to the second chamber;
a wafer stage positioned inside the second chamber and having a wafer support surface;
a first chamber shutter positioned between the grid and the first chamber;
a second chamber shutter positioned between the grid and the second chamber;
a stage voltage supply;
a plurality of radio frequency (RF) coils positioned at an outer wall of the first chamber; and
an RF power supply configured to supply power to the plurality of RF coils,
wherein the stage voltage supply is configured to apply a voltage to the wafer stage when the second gas is injected into the second chamber,
the first chamber shutter and the second chamber shutter are each configured to slide in a direction parallel to a direction in which the grid extends between an open state in which the grid is fluidly connected to the first chamber and the second chamber and a closed state in which the grid is not fluidly connected to the first chamber and the second chamber,
the second chamber shutter includes:
a first surface facing the second chamber and including an oxide film; and
a second surface opposite to the first surface and including a metal film,
the first gas injector is further configured to supply the first gas only when the first chamber shutter and the second chamber shutter are in an open state, and
the second gas injector is further configured to supply the second gas only when the first chamber shutter and the second chamber shutter are in a closed state.

20. The plasma processing device of claim 19, wherein the plurality of RF coils are configured to apply RF power to the first chamber to generate first plasma from the first gas,
the first plasma is configured to pass through the grid to perform ion beam etching on a wafer,
the second chamber is configured to separate the second gas into ions and electrons in the second chamber, and
the ions are configured to remove a redeposited metal that is separated from the wafer on which the ion beam etching has been performed.
